(19) United States
(12) Patent Application Publication
(10) Pub. No.: US 2021/0242299 A1
(43) Pub. Date: Aug. 5, 2021

(54) DISPLAY DEVICE

(71) Applicant: Japan Display Inc., Tokyo (JP)

(72) Inventor: Takashi SAEKI, Tokyo (JP)

(73) Assignee: Japan Display Inc., Tokyo (JP)

(21) Appl. No.: 17/238,223

(22) Filed: Apr. 23, 2021

Related U.S. Application Data
(63) Continuation of application No. PCT/JP2019/035471, filed on Sep. 10, 2019.

(30) Foreign Application Priority Data
Oct. 25, 2018 (JP) 2018-200917

(51) Int. Cl. H01L 27/32; H01L 51/00

(52) U.S. Cl. CPC H01L 27/3276; H01L 25/18; H01L 2251/5338; H01L 51/0097

(57) ABSTRACT

A display device includes: a flexible substrate having a first region and a second region arranged in a length direction, the flexible substrate having the second region bent around an axis extending in a width direction perpendicular to the length direction; a display circuit layer in the first region on the flexible substrate, the display circuit layer configured to display an image; a lead-out line on the flexible substrate, the lead-out line extending from the display circuit layer to the second region; and a conductive shield inside and/or outside a bend of the second region on the flexible substrate, the conductive shield covering the lead-out line.

### CROSS-REFERENCE TO RELATED APPLICATION

This application is a continuation application of International Application PCT/JP2019/035471 filed on Sep. 10 2019, which claims priority from Japanese patent application JP2018-200917 filed on Oct. 25, 2018. The contents of these applications are incorporated herein by reference in their entirety.

### BACKGROUND

### 1. Field

The disclosure relates to a display device.

### 2. Description of the Related Art

Radiation noises are a problem in a flexible display using organic electroluminescence (JP 2015-82049A). This is due to factors such as increase of driving frequency by high definition and high-current and high-speed switching specific to the organic electroluminescence.

In commercializing the flexible display, there is a known structure in which lines are bent near the display area to achieve a narrow picture frame. In this structure, making the lines long on the bent portion leads to increase in radiation noises, partly because of a high signal voltage due to application of single transmission instead of differential transmission in this area. Therefore, measures need to be taken against the radiation noises from the bent portion.

### SUMMARY

The disclosure aims at measures against radiation noises. A display device includes: a flexible substrate having a first region and a second region arranged in a length direction, the flexible substrate having the second region bent around an axis extending in a width direction perpendicular to the length direction; a display circuit layer in the first region on the flexible substrate, the display circuit layer configured to display an image; a lead-out line on the flexible substrate, the lead-out line extending from the display circuit layer to the second region; and a conductive shield inside and/or outside a bend of the second region on the flexible substrate, the conductive shield covering the lead-out line.

The conductive shield can shield radiation noises.

### BRIEF DESCRIPTION OF THE DRAWINGS

FIG. 1 is a plan view of a display device in a first embodiment.

FIG. 2 is an enlarged II-II sectional view of the display device in FIG. 1.

FIG. 3 is an enlarged view of a portion III of a display in FIG. 2.

FIG. 4 is a circuit diagram of the display device in FIG. 1.

FIG. 5 is an enlarged view of a portion V of the display device in FIG. 2.

FIG. 6 is a cross-sectional view of a display device in a second embodiment.

FIG. 7 is an exploded view of a display device in a third embodiment.

FIG. 8 is an exploded view of a display device in a fourth embodiment.

FIG. 9 is an exploded view of a display device in a fifth embodiment.

FIG. 10 is a X-X sectional view of a display device in FIG. 9.

### DETAILED DESCRIPTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

### First Embodiment

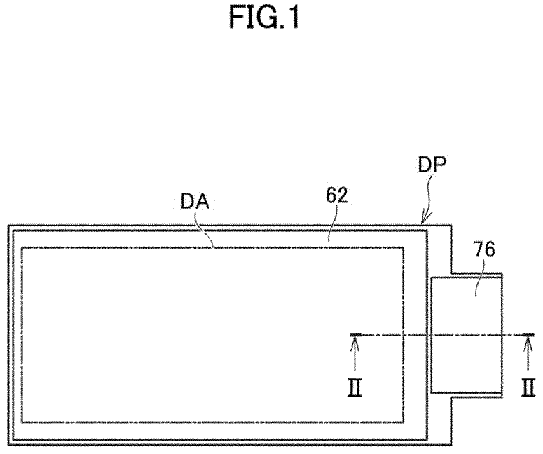

FIG. 1 is a plan view of a display device in a first embodiment. The display device includes a display DP. The display DP is, for example, an organic electroluminescent display. The display DP has flexibility and is bent outside the display area DA in which an image is displayed. In the display area DA, for example, some unit pixels (sub-pixels) in colors such as red, green, and blue are combined to form a full-color pixel, and a full-color image is displayed.

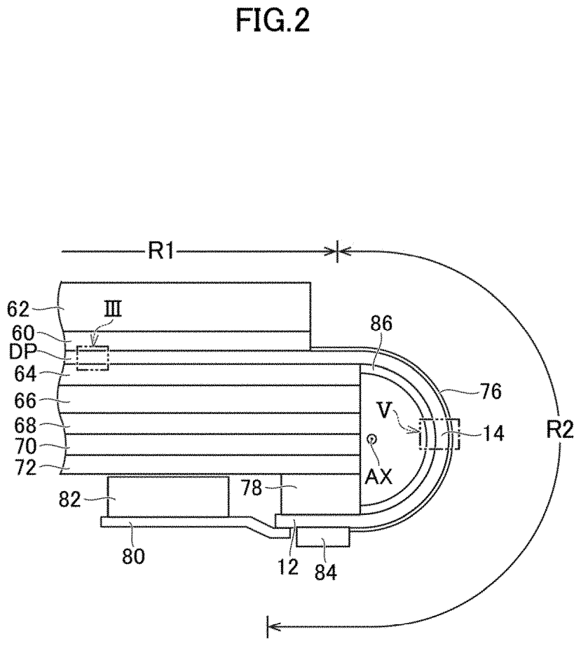

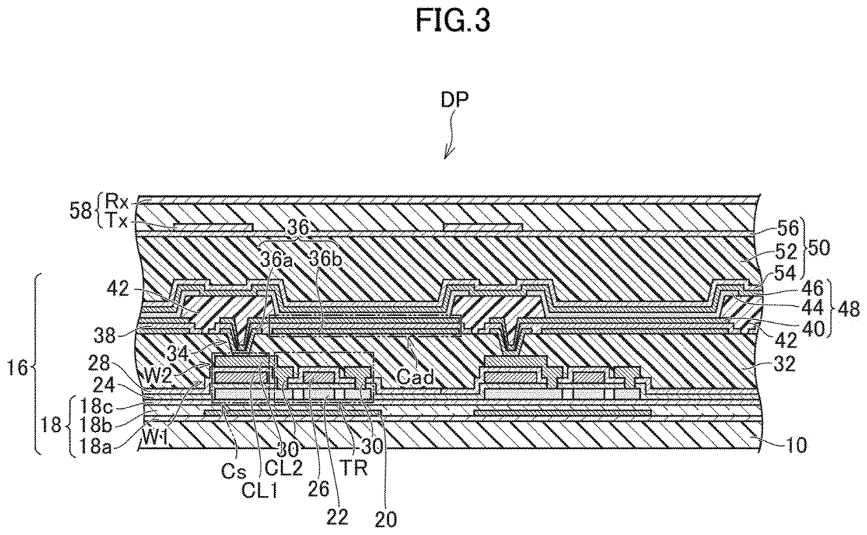

FIG. 2 is an enlarged II-II sectional view of the display device in FIG. 1. FIG. 3 is an enlarged view of a portion III of the display DP in FIG. 2. The display device (display DP) has a flexible substrate 10. The flexible substrate 10 is made of polyimide, but other resin materials may be used as long as the substrate has sufficient flexibility to constitute a sheet display or a flexible display. The flexible substrate 10 has a first region R1 and a second region R2 arranged in the length direction. The flexible substrate 10 is bent in the second region R2 around an axis AX extending in the width direction perpendicular to the length direction. The second region R2 has a curved portion 14 between the first region R1 and the end portion 12 (opposite to the first region R1).

The display has a display circuit layer 16. The display circuit layer 16 is provided on the flexible substrate 10 in the first region R1 for displaying an image. A barrier inorganic film 18 (undercoat layer) is laminated on the flexible substrate 10. The barrier inorganic film 18 has a three-layer laminated structure consisting of a silicon oxide film 18a, a silicon nitride film 18b, and a silicon oxide film 18c. The lowest silicon oxide film 18a is for improving adhesion to the flexible substrate 10, the middle silicon nitride film 18b is for a block film against moisture and impurities from the outside, the uppermost silicon oxide film 18c is for a block film to prevent hydrogen atoms contained in the silicon nitride film 18b from diffusing in the semiconductor layer 22 side of the thin film transistor TR, although this structure is changeable, another layer may be further laminated, or a single layer or a double layer lamination is applicable.

An additional film 20 may be formed at a position where a thin film transistor TR is formed. The additional film 20 can suppress change in characteristics of the thin film transistor TR possibly due to penetration of light from the back of the channel, or can provide a predetermined potential by being formed from a conductive material to give a back gate effect to the thin film transistor TR. Here, after the silicon oxide film 18a is formed, the additional film 20 is formed in an island shape in accordance with the position where the thin film transistor TR is formed, and then the silicon nitride film 18b and the silicon oxide film 18c are laminated, so that the additional film 20 is sealed in the barrier inorganic film 18; instead, the additional film 20 may be formed first on the flexible substrate 10, and then the barrier inorganic film 18 may be formed.

The thin film transistor TR is formed on the barrier inorganic film 18. A polysilicon thin film transistor is exemplified here, and only an N-channel transistor is shown, but a P-channel transistor may be formed at the same time. The semiconductor layer 22 of the thin film transistor TR has a structure in which a low concentration impurity region is provided between a channel region and a source/drain region. A silicon oxide film is used here as a gate insulating film 24. A gate electrode 26 is part of a first wiring layer W1 formed of MoW. The first wiring layer W1 has a first holding capacitance line CL1 in addition to the gate electrode 26. There is a portion of a holding capacitor Cs between the first holding capacitance line CL1 and the semiconductor layer 22 (source/drain region), via the gate insulating film 24.

There is an interlayer insulating film 28 (silicon oxide film, silicon nitride film) laminated on the gate electrode 26. There is a second wiring layer W2, including a portion serving as the source/drain electrode 30, on the interlayer insulating film 28. Here, a three-layer laminated structure of Ti, Al, and Ti is employed. The first holding capacitance line CL1 (part of the first wiring layer W1) and the second holding capacitance line CL2 (part of the second wiring layer W2), via the interlayer insulating film 28, constitute another part of the holding capacitor Cs.

A flattening organic film 32 is provided to cover the source/drain electrode 30. The flattening organic film 32 is superior in surface flatness to inorganic insulating materials possibly formed by CVD (Chemical Vapor Deposition), therefore resins such as photosensitive acrylic are used.

The flattening organic film 32 is removed in the pixel contact portion 34, and an indium tin oxide (ITO) film 36 is formed thereon. The indium tin oxide film 36 includes a first transparent conductive film 36a and a second transparent conductive film 36b separated from each other.

The second wiring layer W2 the surface of which is exposed by the removal of the flattening organic film 32 is covered with the first transparent conductive film 36a. A silicon nitride film 38 is provided on the flattening organic film 32 to cover the first transparent conductive film 36a. The silicon nitride film 38 has an opening at the pixel contact portion 34, the pixel electrode 40 is laminated to be electrically continuous to the source/drain electrode 30 through the opening. The pixel electrode 40 is formed as a reflective electrode, and has a three-layer laminated structure of an indium zinc oxide film, an Ag film, and an indium zinc oxide film. Here, an indium tin oxide film may be used instead of the indium zinc oxide film. The pixel electrode 40 extends laterally from the pixel contact portion 34 and to above the thin film transistor TR.

The second transparent conductive film 36b is disposed below the pixel electrode 40 (further below the silicon nitride film 38) adjacent to the pixel contact portion 34. The second transparent conductive film 36b, the silicon nitride film 38, and the pixel electrode 40 overlap with each other and constitute the additional capacitance Cad.

On the flattening organic film 32, for example, above the pixel contact portion 34, an insulating organic film 42 called a bank (rib) and serving as a partition wall of the adjacent pixel regions is formed. The insulating organic film 42 may be formed from photosensitive acrylic just like the flattening organic film 32. The insulating organic film 42 has an opening to expose the surface of the pixel electrode 40 as a light emitting region, its open end should be preferably in a gently tapered shape. A steep shape of the open end causes poor coverage of the organic electroluminescence layer 44 formed thereon.

The flattening organic film 32 and the insulating organic film 42 are in contact with each other through an opening provided in the silicon nitride film 38 between them. As a result, moisture and gas desorbed from the flattening organic film 32 can be extracted through the insulating organic film 42 during heat treatment after the formation of the insulating organic film 42.

An organic electroluminescence layer 44 made of organic materials is laminated on the pixel electrode 40. The organic electroluminescence layer 44 may be a single layer, or may have a structure in which a hole transport layer, a light emitting layer, and an electron transport layer are laminated in this order from the pixel electrode 40 side. These layers may be formed by evaporation, may be formed by coating after solvent dispersion, may be formed selectively on the pixel electrodes 40 (sub-pixels), or may be widely formed on the entire surface covering the display region DA. In the case of wide formation, white light is obtained in all sub-pixels, and a desired color wavelength portion is extracted by a color filter (not shown).

A counter electrode 46 is provided on the organic electroluminescence layer 44. Here, a top emission structure is employed, therefore the counter electrode 46 is transparent. For example, an Mg layer and an Ag layer are formed as a thin film enough to pass light emitted from the organic electroluminescence layer 44. According to the order of formation of the organic electroluminescence layer 44 described above, the pixel electrode 40 is an anode, and the counter electrode 46 is a cathode. A light emitting element layer 48 is composed of the pixel electrodes 40, the counter electrode 46, and an organic electroluminescence layer 44 interposed between the central portion of each pixel electrode 40 and the counter electrode 46. The light emitting element layer 48 includes the display region DA in which the image is displayed.

A sealing layer 50 covering the light emitting element layer 48 is formed on the counter electrode 46. The sealing layer 50 has a function of preventing external moisture from entering the organic electroluminescence layer 44 formed previously, and is required to have a high gas barrier property. The sealing layer 50 has a laminated structure of an organic film 52, and a first inorganic film 54 and a second inorganic film 56 (e.g., silicon nitride films) sandwiching the organic film 52 from above and below. The first inorganic film 54 and the second inorganic film 56 overlap with and in contact with each other around the organic film 52.

A touch sensing layer 58 is laminated on the sealing layer 50. The touch sensing layer 58 has a plurality of transmitting electrodes Tx and a plurality of receiving electrodes Rx intersecting each other below and above an insulating film; alternatively, the counter electrode 46 may be divided into some pieces and be used also for the transmitting electrodes, whereby the transmitting electrodes Tx can be omitted.

As shown in FIG. 2, a polarizing plate 60 (e.g., circularly polarized plate) and a cover glass 62 are laminated on the display DP. Further, a back film 64, a cushion sheet 66, a polyimide film 68, a graphite film 70, and a copper film 72 are laminated under the display DP.

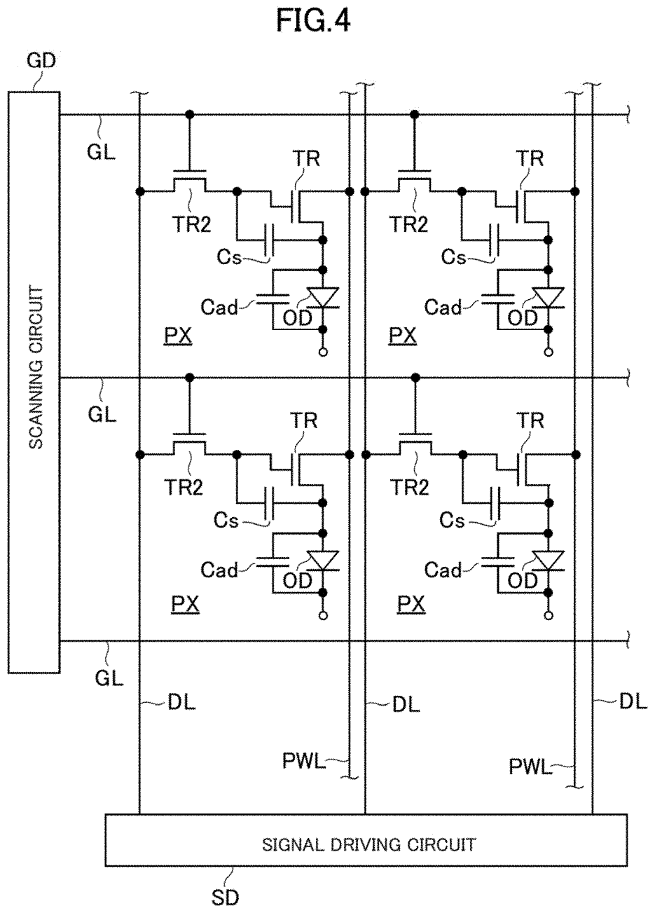

FIG. 4 is a circuit diagram of the display device in FIG. 1. The circuit has a plurality of scanning lines GL connected to a scanning circuit GD, a plurality of signal lines DL connected to a signal driving circuit SD. The signal drive circuit SD is disposed on a integrated circuit chip 84 (FIG. 2). An area surrounded by two adjacent scanning lines GL and two adjacent signal lines DL is one pixel PX. The pixel PX includes the thin film transistor TR as a driving transistor and a thin film transistor TR2 as a switch, and a holding capacitor Cs. By applying the gate voltage to the scanning line GL, the thin film transistor TR2 is turned on, the video signal is supplied from the signal line DL, and charge is accumulated in the holding capacitor Cs. The accumulated charge in the holding capacitor Cs turns on the thin film transistor TR, a current flows from a power supply line PWL to the light emitting element OD. This current causes the light emitting element OD to emit light.

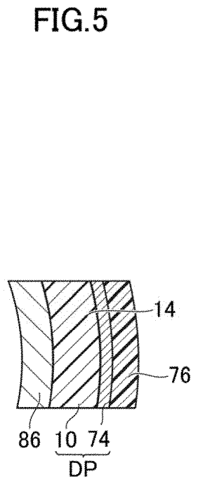

FIG. 5 is an enlarged view of a portion V of the display device in FIG. 2. The display has a lead-out line 74. The lead-out line 74 is formed on the flexible substrate 10 and extends from the display circuit layer 16 in FIG. 3 to the second region R2. A protective layer 76 covers the lead-out line 74. The end portion 12 of the flexible substrate 10 (FIG. 2) is fixed to the side of the display DP via a spacer 78. Further, a flexible printed circuit board 80 is connected to the end portion 12 of the flexible substrate 10. A fingerprint sensor 82 is mounted on the flexible printed circuit board 80.

The integrated circuit chip 84 (driver IC) is mounted on the flexible substrate 10 at the end portion 12 or a position closer to the end portion 12 than the curved portion 14. The input signal to the integrated circuit chip 84 is a differential signal pair (digital signal with amplitude of approximately 5 V or less), whereas the output signal from the integrated circuit chip 84 is a single-ended signal (gradation analog signal with amplitude of substantially more than 5 V, about 5 to 20 V). The output signal passes through lead-out line 74. The longer the lead-out wiring 74 is, the more the inductance component becomes. Also, the single-ended signal has a large signal amplitude. These are factors of worsening radiation noises.

The display has a conductive shield 86. The conductive shield 86 is inside and/or outside the bend of the second region R2 (only inside in FIG. 5). The conductive shield 86 is provided on the flexible substrate 10 so as to cover (or overlap with) the lead-out line 74.

The conductive shield 86 is formed by applying a conductive paste or a conductive sheet to the flexible substrate 10. The conductive paste is obtained by mixing conductive filler such as carbon black, graphite powder, noble metal powder, copper powder, or nickel powder, and resin solvent serving as a binder, into a paste shape. As the metal as the conductive particles, silver, copper, or nickel is generally used. A conductive paste having excellent flexibility or elasticity is desirable.

In the manufacturing process, after the integrated circuit chip 84 is mounted on the flexible substrate 10, a resin is applied to a portion to be the curved portion 14 to form the protective layer 76. The optimum film thickness and Young's modulus of the protective layer 76 are selected so that the lead-out line 74 is disposed on the neutral plane of the total thickness of the protective layer 76, the lead-out line 74, and the flexible substrate 10. Then, the conductive paste is applied to the region to be the curved portion 14 of the flexible substrate 10 possibly by a dip method, and the portion is bent. Alternatively, the second region R2 of the flexible substrate 10 may be bent, then the conductive paste may be applied, or a conductive sheet may be attached.

According to the present embodiment, the conductive shield 86 can shield the radiation noises.

### Second Embodiment

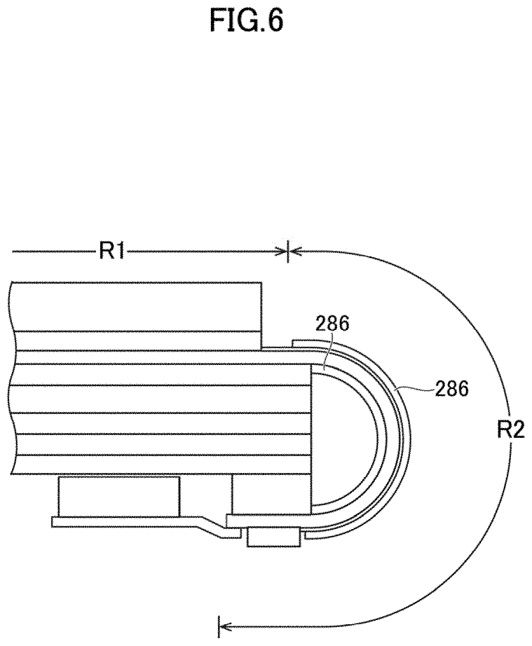

FIG. 6 is a cross-sectional view of a display device in a second embodiment. In this embodiment, the conductive shield 286 is both inside and outside the bend of the second region R2. For example, the conductive paste is applied or the conductive sheet is attached to the front of the bend, and the conductive paste is filled on the back. What is explained in the first embodiment is applicable to other details.

### Third Embodiment

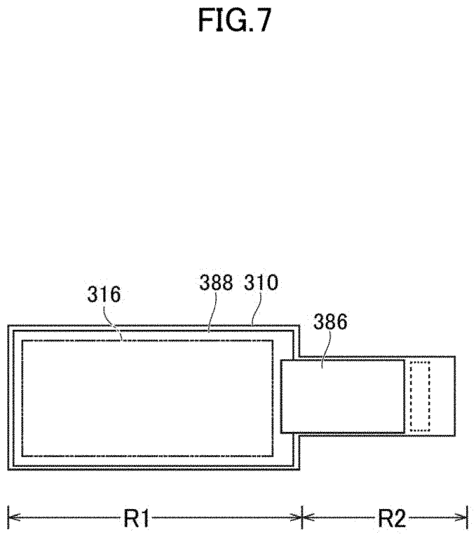

FIG. 7 is an exploded view of a display device in a third embodiment. In this embodiment, the metal sheet 388 is laminated on the flexible substrate 310. The metal sheet 388 overlaps with the first region R1, on the side (back) opposite to the display circuit layer 316. The conductive shield 386 is electrically connected to the metal sheet 388. The conductive shield 386 and the metal sheet 388 are connected to ground. What is explained in the first embodiment is applicable to other details.

### Fourth Embodiment

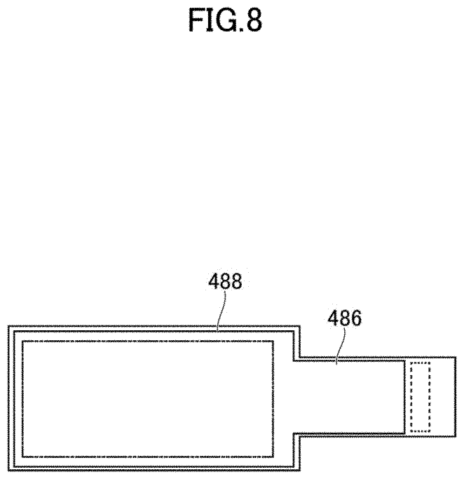

FIG. 8 is an exploded view of a display device in a fourth embodiment. In this embodiment, the conductive shield 486 and the metal sheet 488 are continuously integrated. What is explained in the first embodiment is applicable to other details.

### Fifth Embodiment

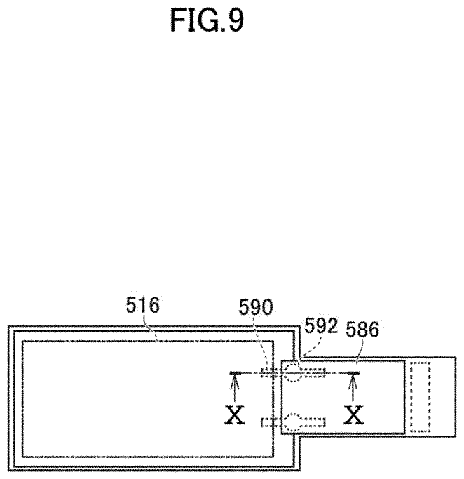

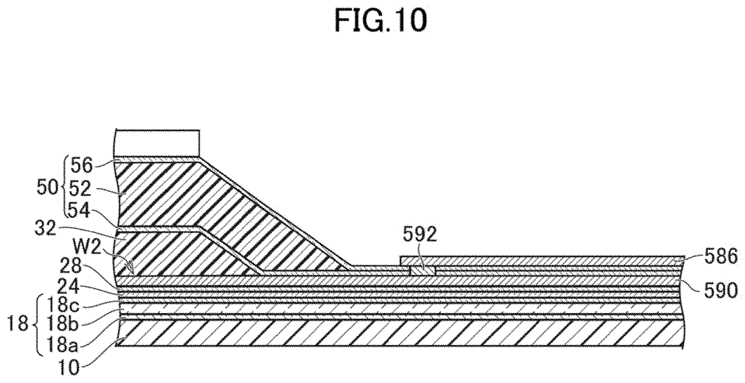

FIG. 9 is an exploded view of a display device in a fifth embodiment. FIG. 10 is a X-X sectional view of a display device in FIG. 9. In this embodiment, the conductive shield 586 is electrically connected to the display circuit layer 516. The conductive shield 586 is connected to ground. The conductive shield 586 should be connected through a connecting portion 592 to the ground line 590 included in the second wiring layer W2 in FIG. 3. This enables the conductive shield 586 to have the ability of sufficiently shielding noises, because the second wiring layer W2 is thick and made from a material with a low resistivity. The sealing layer 50 has no organic film 52 at the peripheral portion and has the first inorganic film 54 and the second inorganic film 56 in contact with each other; the connection portion 592 penetrates the first inorganic film 54 and the second inorganic film 56 which overlap with each other (and other insulating film, if necessary), whereby the conductive shield 586 and the ground line 590 are connected to each other. What is explained in the first embodiment is applicable to other details.

The embodiments described above are not limited and different variations are possible. The structures explained in the embodiments may be replaced with substantially the same structures and other structures that can achieve the same effect or the same objective.

What is claimed is:

1. A display device comprising:
a flexible substrate having a first region and a second region arranged in a length direction, the second region bent around an axis extending in a width direction perpendicular to the length direction;
a display circuit layer in the first region on the flexible substrate, the display circuit layer configured to display an image;
a lead-out line on the flexible substrate, the lead-out line extending from the display circuit layer to the second region; and
a conductive shield inside and/or outside the second region bending around, the conductive shield overlapping the lead-out line.

2. The display device according to claim 1, wherein
the second region has a curved portion between the first region and an end portion, and
the display device further comprises an integrated circuit chip on the flexible substrate at a position closer to the end portion than the curved portion.

3. The display device according to claim 1, wherein the conductive shield is electrically connected to the display circuit layer.

4. The display device according to claim 1, wherein the conductive shield is connected to a ground potential.

5. The display device according to claim 1, further comprising a metal sheet laminated on the flexible substrate on a side opposite to the display circuit layer, the metal sheet overlapping with the first region,
wherein the conductive shield is electrically connected to the metal sheet.

6. The display device according to claim 5, wherein the conductive shield and the metal sheet are continuously integrated.
